(19) United States
(12) Patent Application Publication
(10) Pub. No.: US 2005/0258897 A1
(43) Pub. Date: Nov. 24, 2005

(54) Amplifier arrangement and method for the compensation of a signal component in an amplifier arrangement

(76) Inventor: Zdravko Boos, Munchen (DE)

Correspondence Address: ESCHWEILER & ASSOCIATES, LLC;NATIONAL CITY BANK BUILDING, 629 EUCLID AVE., SUITE 1210, CLEVELAND, OH, 44114, US

(21) Appl. No.: 11/129,161

(22) Filed: May 13, 2005

(30) Foreign Application Priority Data
May 19, 2004 (DE) 10 2004 024 875.3

(51) Int. Cl. H03F 3/52

(52) U.S. Cl. 330/98

(57) ABSTRACT

An amplifier arrangement having a first amplifier stage and at least one second amplifier stage is provided, an input of the second amplifier stage being connected to the output of the first amplifier stage. The first amplifier stage and also the second amplifier stage are in each case designed for amplification with an adjustable discrete gain factor. Furthermore, provision is made of a feedback path connected between the output of the at least one second amplifier circuit and the input of the first amplifier stage. The feedback path is designed for generating and outputting a signal to the input of the first amplifier stage for the compensation of an offset signal at the output of the at least one second amplifier stage. Said offset signal is brought about by a setting of the gain factor of the first and/or the second amplifier stage.

### REFERENCE TO RELATED APPLICATIONS

This application claims the benefit of the priority date of German application DE 10 2004 024 875.3, filed on May 19, 2004, the contents of which are herein incorporated by reference in their entirety.

### FIELD OF THE INVENTION

The invention relates to an amplifier arrangement and to a use of a first and a second amplifier arrangement in a receiver arrangement. Furthermore, the invention relates to a method for the compensation of a signal component in an amplifier arrangement comprising at least two series-connected amplifier stages having adjustable discrete gain factors.

### BACKGROUND OF THE INVENTION

In modern mobile radio systems, for example in third-generation mobile radio systems, distortion-free amplification both in the transmission path and in the reception path is of particular importance. Thus, some mobile radio standards, such as UMTS or GSM/edge, prescribe reducing or increasing the signal level during a data transmission. The reception quality and also the transmission quality are not to be influenced in this case. A distinction can be made between two basic principles for controlling the gain.

One possibility is a continuous, analog gain control, which is referred to as AGC (Automatic Gain Control). In this case, the gain is altered in analog fashion, i.e. continuously, to the desired value. By contrast, a programmable gain control provides for changing the gain in discrete steps. In the case of discrete jumps in the gain, the term used is a PGC (Programmable Gain Control) amplifier circuit.

The respective gain factor for setting the gain is fed to the corresponding circuit by means of a control signal. In the case of an analog, continuous gain, this is usually effected by means of a continuous voltage signal that is applied to an actuating input of the amplifier. An amplifier whose gain factor is adjustable in programmable value-discrete fashion has a digital interface for feeding in an actuating signal. On account of this interface, a PGC amplifier, in contrast to an amplifier with an analog actuating input, is less sensitive to voltage fluctuations of the actuating signal. An amplifier chain having a plurality of series-connected amplifiers whose gain factor is adjustable in value-discrete fashion additionally permits a more distinct and more flexible embodiment between the radiofrequency signal processing and the baseband signal processing of a transceiver. In particular, it becomes possible to interconnect a plurality of baseband circuits from different manufacturers.

In order to obtain a sufficient quality of a received signal for the further signal processing, it is necessary in the reception path to provide an amplification of a received signal using suitable means. The amplification may be effected both in a region of the receiver that is designed for radiofrequency signal processing and in the baseband circuits. On account of the distinctly lower current consumption and the simple integration that is additionally present, a suitable amplification of a received signal is very often carried out after a conversion into a baseband signal. In this case, the expression baseband signal denotes a signal having a distinctly lower frequency compared with the frequency of the received signal.

In modern communication systems, an amplification is effected in 1 dB steps, for example, within the receiver path by means of amplifiers that can be programmed with discrete gain factors. However, the use of an amplifier chain with amplifier stages that can be programmed in value-discrete fashion generates a dynamic offset in the case of a parasitic, static DC signal component within the baseband signal of the receiver path, which offset can considerably reduce the quality of the received signal for the further signal processing.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to the more detailed description that is presented later.

An amplifier arrangement is provided that provides an amplified signal with a sufficient signal quality for downstream circuits in accordance with an aspect of the present invention.

Thus, an amplifier arrangement has a first amplifier stage having a first adjustable discrete gain factor and also at least one second amplifier stage having a second adjustable discrete gain factor. The at least one second amplifier stage is connected to an output of the first amplifier stage by an input. A feedback path is connected between an output of the at least one second amplifier stage and the input of the first amplifier stage. Said feedback path is designed for generating and for outputting a signal at the input of the first amplifier stage. In this case, the generated signal is such that this results in a compensation of an offset signal at the output of the at least one second amplifier stage, said offset signal being brought about by a setting of the first and/or the second gain factor.

A design of the amplifier arrangement with a control loop and a feedback path thus compensates for signal components which are brought about as a result of a change in the gain factor within the amplifier arrangement. Such a change in the gain factor of one of the at least two amplifier stages produces a dynamic signal component at the output of the amplifier arrangement according to the invention provided that an input signal with a DC signal component, in particular, is present. The signal component thus generated is processed in the feedback path and fed to the input of the amplifier arrangement in such a way that the DC signal component present on the input side is distinctly reduced thereby.

In another aspect, the feedback path comprises an integrating circuit having a time constant. The time constant of the integrating circuit results in a frequency response of the integrating circuit. Depending on a switching speed of the individual amplifier stages in the case of a change in the gain factors, additional signal components are generated which are processed in a suitable manner with the aid of the integrating circuit. The integrating circuit generates a signal that is added to the signal present on the input side.

In another aspect of the invention, the feedback path has a capacitor, or a varactor diode or a filter in its integrating circuit. Preferably, the capacitance of capacitors or the varactor diodes is variable. The filter may also be designed as a gmC filter with an adjustable frequency response.

In a method for the compensation of a signal component, an amplifying arrangement is provided which comprises at least two series-connected amplifier stages having adjustable discrete gain factors in each case. In this case, the amplifying arrangement may be assigned a total adjustable discrete gain factor as a sum of the at least two adjustable discrete gain factors. After application of a signal for amplification to the input of the amplifier arrangement, a gain factor of at least one of the at least two amplifier stages within the amplifier arrangement is changed over or set anew. This results in a transformation of a DC signal component present in static fashion in the applied signal into a dynamic signal component. This component is fed back, processed and subtracted from the signal applied on the input side. This results in a compensation of the signal component brought about by the changeover or setting in the signal amplified by the amplifier arrangement.

Such an amplifier arrangement according to the invention is can be used in a receiver arrangement, a frequency conversion device being connected upstream of the amplifier arrangement. In another aspect, a first and a second amplifier arrangement are used in a receiver arrangement, and a frequency conversion device for generating a signal having an inphase component and a quadrature component is in this case connected upstream of the first and the second amplifier arrangement.

To the accomplishment of the foregoing and related ends, the following description and annexed drawings set forth in detail certain illustrative aspects and implementations of the invention. These are indicative of but a few of the various ways in which the principles of the invention may be employed. Other aspects, advantages and novel features of the invention will become apparent from the following detailed description of the invention when considered in conjunction with the drawings.

### BRIEF DESCRIPTION OF THE DRAWINGS

The invention is explained in detail below on the basis of an exemplary embodiment with reference to a drawing, in which:

FIG. 1 shows an exemplary embodiment of the amplifier arrangement according to the invention.

FIG. 2 shows a detail from the feedback path of the amplifier arrangement according to the invention.

### DETAILED DESCRIPTION OF THE INVENTION

One or more implementations of the present invention will now be described with reference to the attached drawings, wherein like reference numerals are used to refer to like elements throughout, and wherein the illustrated structures are not necessarily drawn to scale.

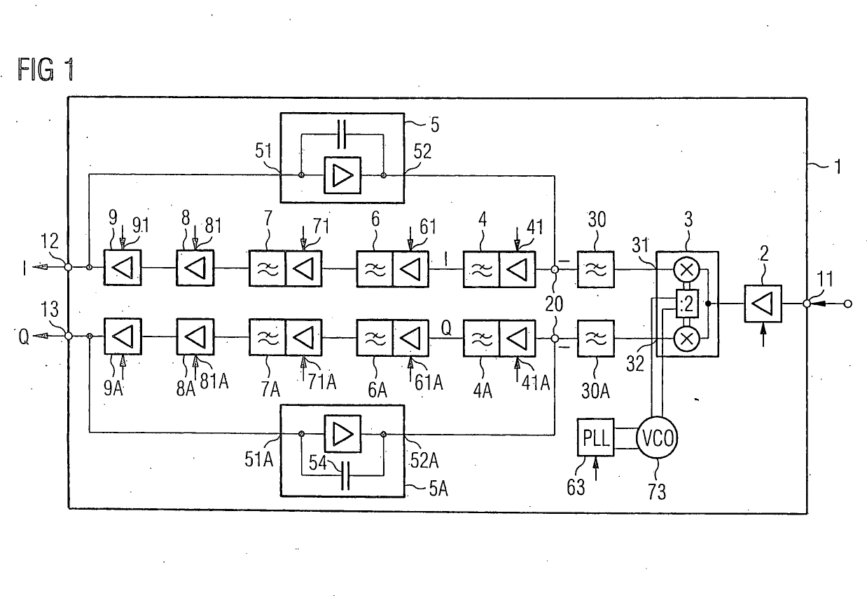

FIG. 1 shows an exemplary embodiment of a receiver path formed as an integrated circuit in a semiconductor body 1. On its surface, the semiconductor body 1 has a plurality of connection contacts for feeding in signals and supply voltages. The connection contacts are formed as contact pads. An input signal is fed to one of said connection contacts 11. Said input signal is formed by a signal which is received via an antenna (not illustrated) and which is conditioned by the arrangement according to the invention and is fed for further signal processing at the outputs 12 and 13.

The input 11 of the receiver path is connected to an input of a low noise input amplifier 2. The low noise input amplifier 2 is designed for an amplification with gain factors that are adjustable in discrete fashion. The low noise amplifier 2 forming the input amplifier enables a signal present on the input side to be amplified in such a way that a sufficient signal strength of the received signal is available to the downstream switching elements and, in particular, the frequency conversion device 3.

The frequency conversion device 3, which is connected to the output of the low noise amplifier by its input, converts the signal present on the input side to a second frequency with the aid of a local oscillator signal. At the same time, the signal present on the input side is decomposed into its inphase component I and its quadrature component Q. Such a frequency conversion device is also referred to as an I/Q demodulator. For this purpose, the demodulator uses a local oscillator signal provided from a phase locked loop, comprising a PLL circuit 63 and a voltage controlled oscillator 73. In this case, the frequency of the voltage controlled oscillator 73 is set such that a signal conversion of the signal present on the input side directly into the baseband signal is effected. This procedure is referred to as direct conversion. A first output 31 of the I/Q demodulator 3 carries the inphase component I of the converted signal, and a second output 32 carries the quadrature component Q.

A low-pass filter 30 and 30a is respectively connected downstream of the outputs 31 and 32. Said filter serves for suppressing higher-frequency signal components generated by the conversion.

The output of the filter 30 is connected to an input of a first amplifier stage 4. The amplifier stage 4 has an individual amplifier and also a low-pass filter directly connected thereto. The amplifier of the stage 4 contains an actuating input 41, to which can be fed a value-discrete actuating signal for setting the gain factor of the amplifier. The amplifier within the amplifier circuit 4 is designed as a programmable amplifier. Via its actuating input 41, the gain of the amplifier stage 4 can thus be changed in value-discrete stages. The low-pass filter connected downstream suppresses higher signal components that are generated by intermodulation during the amplification.

Two further amplifier circuits 6 and 7 are connected downstream of the output of the amplifier circuit 4. The construction of the two amplifier stages 6 and 7 is the same as the construction of the amplifier stage 4. Connected to the output of the amplifier circuit 7 is a further programmable amplifier 8, to which a programmable amplifier 9 is connected. The entire amplifier chain thus comprises five cascaded programmable amplifier stages which in each case respectively contain an actuating input for feeding in an actuating signal for a setting of the gain factor. In this case, the gain factor of each stage is set by means of an actuating signal at the actuating input. The individual amplifier stages are independent in terms of their setting.

The output of the last amplifier 9 within the amplifier chain leads to the output 12, at which the amplified inphase component I of the received and frequency-converted signal can be tapped off. The amplifier chain for the quadrature component Q is constructed in the same way.

A change in the gain setting as a result of feeding in or changing the actuating signals at the inputs 41, 61, 71, 81 or 91 produces an abrupt alteration of the gain of the received signal. In the case of DC current components at the input of the amplifier chain, this abrupt alteration in the gain factor leads to a dynamic signal component which has different spectral bandwidths depending on the change in gain. These additional spectral components cannot be filtered by filters connected downstream. In signal processing circuits connected downstream, this can lead to an error during the demodulation of the received signal.

Therefore, a feedback path is connected to the output of the amplifier 9 for the inphase component I and, respectively, to the amplifier 9a for the quadrature component Q, which feedback path processes further the signal component brought about on account of a change in gain and feeds it once again to the input of the amplifier chain and thereby reduces the DC signal component. This is effected in the exemplary embodiment, as illustrated, by means of a circuit 5 or 5a, respectively, whose input 51 or 51a is connected to the output 9 or 9a, respectively. In this case, the circuit 5 is constructed as an integrator and passes the integrated DC signal component via its output 52 or 52a, respectively, to a summation element 20. Said summation element is respectively connected between the low-pass filter 30 or 30a and the input of the amplifier chain.

In the exemplary embodiment illustrated, the element 20 subtracts the DC signal component from the signal that has been received and output by the low-pass filter 30 or 30a, respectively, and feeds the result to the input of the amplifier chain. By virtue of a suitable choice of the integrating element within the integrator 5 or 5a, it is possible to set a suitable filter characteristic and thus a suitable time constant.

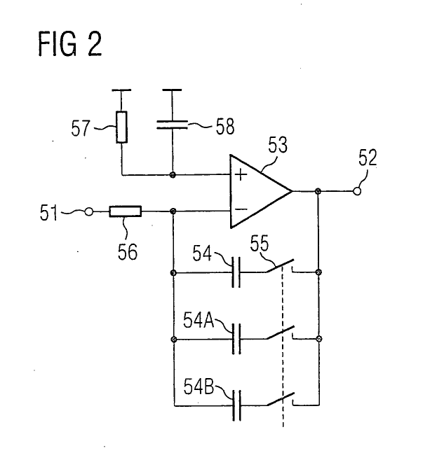

An exemplary embodiment of an integrator which can be used in the amplifier arrangement according to the invention is shown in FIG. 2. In this case, the integrator comprises an operational amplifier 53, the inverting input of which, via a resistor 56, forms the input 51 of the integrator. The noninverting input + is connected to the ground potential via a resistor 57 and also a capacitor 58 connected in parallel therewith. The capacitor 58 serves for decoupling any noise on the ground line or a noise behavior of the resistor 57. The output of the operational amplifier 53 simultaneously forms the output 52 of the integrator 5. A plurality of parallel-connected capacitors 54, 54a and 54b are arranged between the output 52 and the inverting input of the operational amplifier 53. One terminal of said capacitors is connected to the inverting input and the second terminal is connected via a switch 55 to the output of the operational amplifier 53. The individual switches are closed by means of an actuating signal. It is thereby possible to achieve an alteration of the time constant of the integrator, so that the feedback has a frequency response dependent thereon.

In this way, it is possible to compensate for gain jumps that are large but undergo gentle transition. In addition to the embodiment illustrated here with the parallel-connected switchable capacitors, it is also possible to realize other solutions for setting the time constant of the integrator. By way of example, it is possible to use adjustable gmC filters or varactor diodes.

Since the generation of a dynamic signal component is dependent on the input signal in the case of a change in gain, large changes in gain are preferably performed when the input signal is as small as possible. In order, by way of example, to realize a jump with a large gain factor which is required for compensating for a gain jump in the low noise amplifier 2, a change in gain is carried out at a suitable input level. Another possibility consists in setting the desired gain during a time period during which transmission is not effected. This is possible in a time slot method, by way of example.

Although the invention has been illustrated and described with respect to one or more implementations, equivalent alterations and modifications will occur to others skilled in the art upon the reading and understanding of this specification and the annexed drawings. In particular regard to the various functions performed by the above described components (assemblies, devices, circuits, systems, etc.), the terms (including a reference to a “means”) used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising.”

### LIST OF REFERENCE SYMBOLS

1: Semiconductor body
2: Low noise amplifier
3: I/Q demodulator
30, 30a: Low-pass filter
20: Summation element
4, 6, 7: Amplifier circuit
8, 8a, 9, 9a: Amplifier stages
5, 5a: Integrators
41, 41a, 61, 61a: Control inputs
71, 71a, 81, 81a: Control inputs
91, 91a: Control inputs
11: Signal input
12, 13: Signal output
51, 51a: Signal input
56, 57: Resistor
58, 54, 54a, 54b: Capacitors
55: Switch
53: Operational amplifier
63: Phase locked loop
73: Voltage controlled oscillator

1. An amplifier arrangement, comprising:
a first amplifier stage having a first adjustable discrete gain factor and having an input and an output;
at least one second amplifier stage having a second adjustable discrete gain factor and having an input connected to the output of the first amplifier stage and an output; and
a feedback path connected between the output of the at least one second amplifier stage and the input of the first amplifier stage, wherein the feedback path generates and outputs a signal to the input of the first amplifier stage, wherein the signal compensates for an offset signal at the output of the at least one second amplifier stage brought about by a setting of the first adjustable discrete gain factor and the second adjustable discrete gain factor.

2. The arrangement of claim 1, wherein the first amplifier stage further comprises an actuating input that receives an actuating signal that sets the first adjustable gain factor.

3. The arrangement of claim 1, wherein the at least one second amplifier stage further comprises an actuating input that receives an actuating signal that sets the second adjustable gain factor.

4. The arrangement of claim 1, wherein the feedback path comprises an integrating circuit.

5. The arrangement of claim 4, wherein the integrating circuit comprises a charge store that sets an integration constant.

6. The arrangement of claim 4, wherein the integrating circuit comprises a filter with an adjustable frequency range for setting an integration constant.

7. The arrangement of claim 4, wherein the integrating circuit comprises a differential amplifier and a charge store, coupled to the differential amplifier.

8. The arrangement of claim 7, wherein a capacitance of the charge store is adjustable.

9. The arrangement of claim 7, wherein the charge store comprises varactor diodes connected in parallel.

10. The arrangement of claim 1, wherein the first amplifier stage comprises a series connected low pass filter.

11. the arrangement of claim 1, wherein the arrangement is formed in a semiconductor body as an integrated circuit.

12. An amplifier arrangement comprising:
a low noise input amplifier that amplifies an input signal according to an adjustable gain factor.
a frequency conversion component that converts the input signal to a baseband signal having a baseband frequency;
a summation component that combines the baseband signal with a feedback signal;
a plurality of cascaded programmable amplifier stages that selectively amplify the baseband signal to provide an output signal; and
an integrator circuit that processes the output signal to obtain the feedback signal.

13. The arrangement of claim 12, wherein the adjustable gain factor of the low noise input amplifier is selected to obtain a desired signal strength prior to conversion by the frequency conversion component.

14. The arrangement of claim 12, wherein the baseband signal has a quadrature and in phase component.

15. The arrangement of claim 12, wherein at least one of the plurality of cascaded programmable amplifier stages comprise a programmable amplifier and a low pass filter connected in series.

16. The arrangement of claim 12, wherein at least one of the plurality of cascaded programmable amplifier stages comprise a programmable amplifier.

17. The arrangement of claim 12, wherein the plurality of cascaded programmable amplifier stages have a plurality of associated gain values selected to obtain a desired gain for the output signal.

18. A method for the compensation of a signal component in an amplifier arrangement, the method comprising:
providing the amplifying arrangement comprising at least two series-connected amplifier stages having adjustable discrete gain factors;
applying a signal to an input of the amplifier arrangement;
changing a gain factor of at least one of the at least two amplifier stages to compensate for a signal component; and
generating the signal component from an output signal of the arrangement and feeding back the signal component to the input of the arrangement.

19. The method of claim 18, wherein generating the signal component comprises integrating the output signal with an adjustable time constant and subtracting the integrated signal component from the integrated output signal.

20. The method of claim 18, wherein changing the gain factor occurs on the signal component having an amplitude less than a threshold amount.
